(19) United States
(12) Patent Application Publication
(10) Pub. No.: US 2024/0186269 A1
(43) Pub. Date: Jun. 6, 2024

(54) BONDED STRUCTURE WITH SECURITY DIE

(71) Applicant: ADEIA SEMICONDUCTOR BONDING TECHNOLOGIES INC., San Jose, CA (US)

(72) Inventor: Belgacem Haba, Saratoga, CA (US)

(21) Appl. No.: 18/061,383

(22) Filed: Dec. 2, 2022

(51) Int. Cl. H01L 23/00; H01L 23/552; H01L 25/065

(52) U.S. Cl. CPC H01L 23/573; H01L 23/552; H01L 24/08; H01L 24/16; H01L 24/32; H01L 24/73; H01L 24/80; H01L 25/0657; H01L 2224/0801; H01L 2224/08057; H01L 2224/08145; H01L 2224/16221; H01L 2224/32221; H01L 2224/73204; H01L 2224/80895; H01L 2224/80896; H01L 2225/06517; H01L 2225/06524; H01L 2225/06568; H01L 2924/1431; H01L 2924/1434

(57) ABSTRACT

A bonded structure is disclosed. The bonded structure can comprise a semiconductor element comprising active circuitry and a security die electrically connected and directly bonded to a surface of the semiconductor element without an adhesive along a bonding interface. The security die can include a security core. The security core can contain an encryption logic and a memory. The security core can be configured to decrypt data to be transferred to the active circuitry and to encrypt signals from the active circuitry.

### BACKGROUND OF THE INVENTION

### Field

The field relates to a bonded structure with a security device die configured to provide encryption and/or decryption circuitry separate from a semiconductor element to which the security device die is bonded.

### Description of the Related Art

Semiconductor chips (e.g., integrated device dies) may include devices (which can comprise patterned processing circuitry and/or active circuitry) containing security-sensitive components for sending and receiving communications which contain valuable and/or proprietary information, structures or devices. For example, such security sensitive components and communications may include an entity's intellectual property, software or hardware security (e.g., encryption) features, privacy data, or any other components or data that the entity may wish to remain secure and hidden from third parties. For example, third party bad actors may utilize various techniques to attempt to access security-sensitive components for economic and/or geopolitical advantage. Accordingly, there remains a continuing need for improving the security of semiconductor chips.

### SUMMARY OF THE INVENTION

In one embodiment, a bonded structure can include: a semiconductor element having active circuitry; and a security die electrically connected and directly bonded to a surface of the semiconductor element without an adhesive along a bonding interface, the security die having a security core; wherein the security core contains an encryption logic and a memory; and wherein the security core is configured to perform at least one of decrypting signals to be transferred to the active circuitry and encrypting signals received from the active circuitry.

In some embodiments, the bonded structure includes vias that electrically connect the security die and the semiconductor element. In some embodiments, the semiconductor element and security die are hybrid bonded such that nonconductive regions of the semiconductor element and the security die are directly bonded and conductive regions of the semiconductor element and the security die are directly bonded.

In some embodiments, the bonded structure includes an obstructive material over the security die, the obstructive material configured to inhibit external access to the security core. In some embodiments, the obstructive material is part of a protective element, the protective element directly bonded to a surface of the security die. In some embodiments, the obstructive material is directly bonded to a back side of the security die. In some embodiments, the obstructive material includes a destructive material having a hardness in a range of 20 GPa to 150 GPa on the Vickers hardness scale. In some embodiments, the obstructive material includes a destructive material having a hardness of at least 80 GPa on the Vickers hardness scale. In some embodiments, the obstructive material includes an abrasive material. In some embodiments, the obstructive material includes a light-blocking material. In some embodiments, the light-blocking material is configured to block light at near infrared (NIR) wavelengths. In some embodiments, the obstructive material includes an optical or infrared (IR) blocking or modifying material.

In some embodiments, an encapsulating material is provided over the semiconductor element and the security die. In some embodiments, the semiconductor element includes a first bonding layer and wherein the security die can include a second bonding layer directly bonded to the first bonding layer without an adhesive. In some embodiments, the first bonding layer includes silicon oxide. In some embodiments, the bonded structure includes a first plurality of contact pads in the first bonding layer and a second plurality of contact pads in the second bonding layer, the first plurality of contact pads directly bonded to the second plurality of contact pads. In some embodiments, the memory stores an encryption key.

In another embodiment, a bonded structure can include: a semiconductor element having active circuitry; a security die electrically connected and directly bonded to a surface of the semiconductor element without an adhesive along a bonding interface, the security die comprising a security core; and an obstructive material disposed over a surface of the security die, the obstructive material configured to inhibit external access to the security core.

In some embodiments, the security core includes an encryption logic and a memory. In some embodiments, the security core is configured to encrypt data to be transferred to the active circuitry and decrypt signals received from the active circuitry. In some embodiments, the obstructive material is part of a protective element, the protective element directly bonded to a surface of the security die. In some embodiments, the bonded structure includes a carrier, the security die mechanically and electrically connected to the carrier. In some embodiments, the bonded structure includes vias that electrically connect the security die and the semiconductor element. In some embodiments, the bonded structure includes vias that electrically connect the security die and the carrier. In some embodiments, the carrier includes a plurality of conductive bumps electrically connected to the semiconductor element and the security die.

In some embodiments, the obstructive material includes a destructive material having a hardness in a range of 20 GPa to 150 GPa on the Vickers hardness scale. In some embodiments, the obstructive material includes a destructive material having a hardness of at least 80 GPa on the Vickers hardness scale. In some embodiments, the obstructive material includes an abrasive material. In some embodiments, the obstructive material includes a light-blocking material. In some embodiments, the light-blocking material is configured to block light at near infrared (NIR) wavelengths. In some embodiments, the obstructive material includes an optical or infrared (IR) blocking or modifying material.

In some embodiments, an encapsulating material is provided over the semiconductor element and the security die. In some embodiments, the semiconductor element includes a first bonding layer and wherein the security die includes a second bonding layer directly bonded to the first bonding layer without an adhesive. In some embodiments, the first bonding layer comprise silicon oxide. In some embodiments, the security die includes a through substrate via.

In another embodiment, a method of forming a bonded structure can include: providing a security die with a security core, the security core containing encryption logic and a memory; directly bonding the security die to a surface of a semiconductor element without an adhesive such that the security die and semiconductor element are electrically connected, the security core configured to perform at least one of decryption of signals to be transferred to the semiconductor element and encryption of signals to be received from the semiconductor element.

In some embodiments, the semiconductor element includes active circuitry. In some embodiments, the method includes connecting vias between the semiconductor element and security die. In some embodiments, the method includes providing an obstructive material over a surface of the security die, the obstructive material configured to prevent external access to the security die. In some embodiments, the method includes providing an encapsulating material over the semiconductor element and the security die.

### BRIEF DESCRIPTION OF THE DRAWINGS

FIG. 1A is a schematic cross sectional side view of two elements prior to direct hybrid bonding.

FIG. 1B is a schematic cross sectional side view of a bonded structure including the two elements shown in FIG. 1A after direct hybrid bonding.

FIG. 2A is a schematic side sectional view of a pre-assembled bonded structure that includes a security chiplet and before being directly bonded to a semiconductor element

FIG. 2B is a schematic side sectional view of a bonded structure including the components of FIG. 2A, according to one embodiment.

FIG. 3 is a schematic side section view of another bonded structure that includes a security chiplet and a semiconductor element connected to a carrier.

FIG. 4 is a schematic side section view of an integrated circuit die having security circuitry disposed on the surface of the die.

### DETAILED DESCRIPTION

### Overview

As explained herein, third parties (such as third-party bad actors) may attempt to access security-sensitive components on elements such as integrated device dies and communications (e.g., signals) containing security-sensitive information to and from the integrated device dies. In some device dies, the integrated device dies may include a security core connected to other active circuitry of the die to encrypt or decrypt signals that are processed by the other active circuitry. The integrated circuit die can be further protected by providing a protective element having an obstructive material along the entirety of a backside of the die as shown in FIG. 4. As explained herein, FIG. 4 illustrates an integrated circuit die 400 comprising a substrate 404 with devices 402 (e.g., one or more active devices, such as transistors, and/or one or more passive devices) disposed on a surface of the substrate 404 and an encapsulating layer 406 (which can comprise a passivation layer, such as an inorganic dielectric) encapsulating the devices 402. Because the die 400 includes a security core connected to other active circuitry, a protective element including an obstructive material 408 can be provided along the entire backside of the die. However, providing a protective element or obstructive material over the entirety of the die can be very costly and time consuming. Additional examples of protective elements with obstructive materials may be found throughout U.S. Publications Nos. 2020/0328162, 2020/0328164, 2020/0371154, and 2020/0328165 and U.S. application Ser. Nos. 17/816,346 and 17/812,675, the entire contents of each of which are incorporated by reference herein in their entirety and for all purposes. Accordingly, there remains a continuing need to provide improved security for elements (such as semiconductor integrated device dies) that include security-sensitive components and/or that securely transmit and/or receive security-sensitive signals.

In order to secure data or signals going into and/or out of a device, the data can be transmitted to a security core. Data received by a processor die, for example, can be transferred to the security core (also referred to herein as an “encryption core”) to be decrypted. The decrypted data can be processed by other active circuitry of the integrated device die. Alternatively or additionally, data being transferred out of the system can be processed by the security core to encrypt the data before the data is transferred to an external device.

One method to reduce costs in safeguarding against hacking is to pattern the security core on a separate security chiplet instead of patterning the security core containing the encryption (and/or decryption) logic and memory on the integrated device die itself. The security chiplet can be thinned and protected against hacking using, e.g., an obstructive material. The security chiplet can be directly hybrid bonded to the integrated device die. By patterning the security core on the security chiplet, protection of the entire host chip may be obviated, which can reduce processing costs. The communication speed between the host processor and the security chip can also be improved since there can be additional connections between the host processor and the security chiplet. The security chiplet offers a versatile option that can be used with a variety of host processors or other types of integrated device dies with devices. Various embodiments disclosed herein accordingly include a security chip or chiplet (with encryption and/or decryption circuitry) directly bonded to an integrated device die with active circuitry.

### Examples of Direct Bonding Methods and Directly Bonded Structures

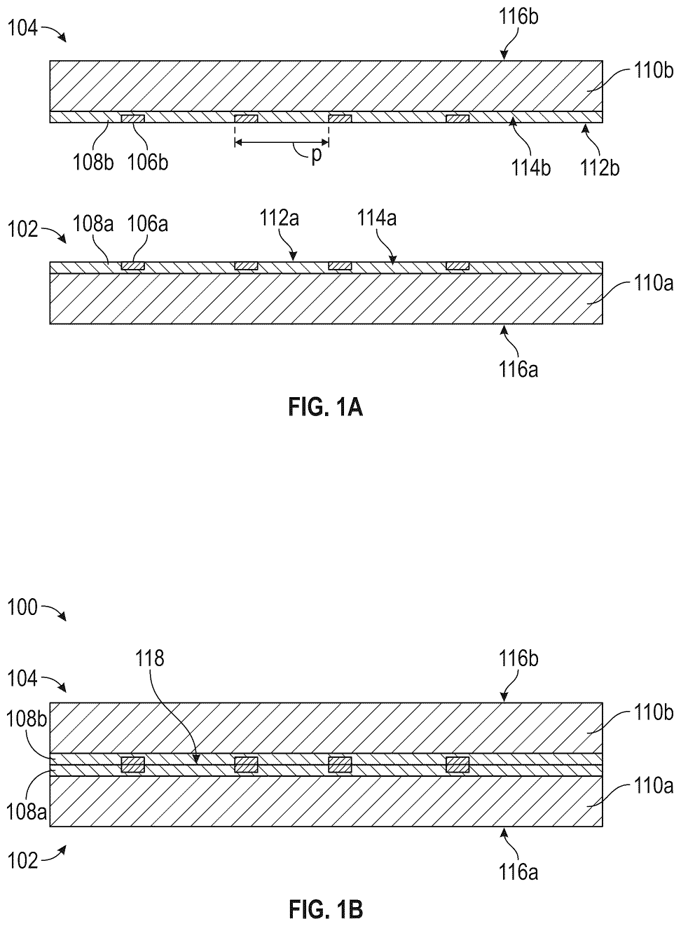

Various embodiments disclosed herein relate to directly bonded structures in which two or more elements can be directly bonded to one another without an intervening adhesive. FIGS. 1A and 1B schematically illustrate a process for forming a directly bonded structure without an intervening adhesive according to some embodiments. In FIGS. 1A and 1B, a bonded structure 100 comprises two elements 102 and 104 that can be directly bonded to one another without an intervening adhesive. Two or more semiconductor elements (such as integrated device dies, wafers, etc.) 102 and 104 may be stacked on or bonded to one another to form the bonded structure 100. Conductive features 106a (e.g., contact pads, exposed ends of vias (e.g., TSVs), or a through substrate electrodes) of a first element 102 may be electrically connected to corresponding conductive features 106b of a second element 104. Any suitable number of elements can be stacked in the bonded structure 100. For example, a third element (not shown) can be stacked on the second element 104, a fourth element (not shown) can be stacked on the third element, and so forth. Additionally or alternatively, one or more additional elements (not shown) can be stacked laterally adjacent one another along the first element 102. In some embodiments, the laterally stacked additional element may be smaller than the second element. In some embodiments, the laterally stacked additional element may be two times smaller than the second element.

In some embodiments, the elements 102 and 104 are directly bonded to one another without an adhesive. In various embodiments, a non-conductive field region that includes a non-conductive or dielectric material can serve as a first bonding layer 108a of the first element 102 which can be directly bonded to a corresponding non-conductive field region that includes a non-conductive or dielectric material serving as a second bonding layer 108b of the second element 104 without an adhesive. The non-conductive bonding layers 108a and 108b can be disposed on respective front sides 114a and 114b of device portions 110a and 110b, such as a semiconductor (e.g., silicon) portion of the elements 102, 104. Active devices and/or circuitry can be patterned and/or otherwise disposed in or on the device portions 110a and 110b. Active devices and/or circuitry can be disposed at or near the front sides 114a and 114b of the device portions 110a and 110b, and/or at or near opposite backsides 116a and 116b of the device portions 110a and 110b. The non-conductive material can be referred to as a non-conductive bonding region or bonding layer 108a of the first element 102. In some embodiments, the non-conductive bonding layer 108a of the first element 102 can be directly bonded to the corresponding non-conductive bonding layer 108b of the second element 104 using dielectric-to-dielectric bonding techniques. For example, non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiments, the bonding layers 108a and/or 108b can comprise a non-conductive material such as a dielectric material, such as silicon oxide, or an undoped semiconductor material, such as undoped silicon. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SICOH dielectrics, silicon carbonitride or diamond-like carbon or a material comprising of a diamond surface. Such carbon-containing ceramic materials can be considered inorganic, despite the inclusion of carbon. In some embodiments, the dielectric materials do not comprise polymer materials, such as epoxy, resin or molding materials.

In various embodiments, direct hybrid bonds can be formed without an intervening adhesive. For example, nonconductive bonding surfaces 112a and 112b can be polished to a high degree of smoothness. The bonding surfaces 112a and 112b can be cleaned and exposed to a plasma and/or etchants to activate the surfaces 112a and 112b. In some embodiments, the surfaces 112a and 112b can be terminated with a species after activation or during activation (e.g., during the plasma and/or etch processes). Without being limited by theory, in some embodiments, the activation process can be performed to break chemical bonds at the bonding surfaces 112a and 112b, and the termination process can provide additional chemical species at the bonding surfaces 112a and 112b that improves the bonding energy during direct bonding. In some embodiments, the activation and termination are provided in the same step, e.g., a plasma to activate and terminate the surfaces 112a and 112b. In other embodiments, the bonding surfaces 112a and 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Further, in some embodiments, the bonding surfaces 112a and 112b can be exposed to fluorine. For example, there may be one or multiple fluorine peaks at or near a bonding interface 118 between the first and second elements 102, 104. Thus, in the directly bonded structure 100, the bonding interface 118 between two non-conductive materials (e.g., the bonding layers 108a and 108b) can comprise a very smooth interface with higher nitrogen content and/or fluorine peaks at the bonding interface 118. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive features 106a of the first element 102 can also be directly bonded to corresponding conductive features 106b of the second element 104. For example, a hybrid bonding technique can be used to provide conductor-to-conductor direct bonds along the bond interface 118 that includes covalently direct bonded non-conductive-to-non-conductive (e.g., dielectric-to-dielectric) surfaces, prepared as described above. In various embodiments, the conductor-to-conductor (e.g., conductive feature 106a to conductive feature 106b) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, non-conductive (e.g., dielectric) bonding surfaces 112a, 112b (for example, inorganic dielectric surfaces) can be prepared and directly bonded to one another without an intervening adhesive as explained above. Conductive contact features (e.g., conductive features 106a and 106b which may be at least partially surrounded by non-conductive dielectric field regions within the bonding layers 108a. 108b) may also directly bond to one another without an intervening adhesive. In various embodiments, the conductive features 106a, 106b can comprise discrete pads at least partially embedded in the non-conductive field regions. In some embodiments, the conductive contact features can comprise exposed contact surfaces of through substrate vias (TSVs). In some embodiments, the respective conductive features 106a and 106b can be recessed below exterior (e.g., upper) surfaces (non-conductive bonding surfaces 112a and 112b) of the dielectric field region or non-conductive bonding layers 108a and 108b, for example, recessed by less than 30 nm, less than 20 nm, less than 15 nm, or less than 10 nm, for example, recessed in a range of 2 nm to 20 nm, or in a range of 4 nm to 10 nm. In various embodiments, prior to direct bonding, the recesses in the opposing elements can be sized such that the total gap between opposing contact pads is less than 15 nm, or less than 10 nm. The non-conductive bonding layers 108a and 108b can be directly bonded to one another without an adhesive at room temperature in some embodiments and, subsequently, the bonded structure 100 can be annealed. Upon annealing, the conductive features 106a and 106b can expand and contact one another to form a metal-to-metal direct bond. Beneficially, the use of Direct Bond Interconnect, or DBI®, techniques commercially available from Adeia of San Jose, CA, can enable high density of conductive features 106a and 106b to be connected across the direct bond interface 118 (e.g., small or fine pitches for regular arrays). In some embodiments, the pitch of the conductive features 106a and 106b, such as conductive traces embedded in the bonding surface of one of the bonded elements, may be less than 40 microns or less than 10 microns or even less than 2 microns. For some applications, the ratio of the pitch of the conductive features 106a and 106b to one of the dimensions (e.g., a diameter) of the bonding pad is less than 5, or less than 3 and sometimes desirably less than 2. In other applications, the width of the conductive traces embedded in the bonding surface of one of the bonded elements may range between 0.3 to 20 microns, e.g., in a range of 0.3 to 3 microns. In various embodiments, the conductive features 106a and 106b and/or traces can comprise copper, although other metals may be suitable.

Thus, in direct bonding processes, a first element 102 can be directly bonded to a second element 104 without an intervening adhesive. In some arrangements, the first element 102 can comprise a singulated element, such as a singulated integrated device die. In other arrangements, as shown in FIGS. 1A and 1B, the first element 102 can comprise a carrier or substrate (e.g., a wafer) that includes a plurality (e.g., tens, hundreds, or more) of device regions that, when singulated, form a plurality of integrated device dies. Similarly, the second element 104 can comprise a singulated element, such as a singulated integrated device die, as shown in FIGS. 1A and 1B. In other arrangements, the second element 104 can comprise a carrier or substrate (e.g., a wafer). The embodiments disclosed herein can accordingly apply to wafer-to-wafer, die-to-die, or die-to-wafer bonding processes. In wafer-to-wafer (W2 W) processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the singulation process (e.g., saw markings if a saw singulation process is used).

As explained herein, the first and second elements 102 and 104 can be directly bonded to one another without an adhesive, which is different from a deposition process. In one application, a width of the first element 102 in the bonded structure is similar to a width of the second element 104. In some other embodiments, a width of the first element 102 in the bonded structure 100 is different from a width of the second element 104. Similarly, the width or area of the larger element in the bonded structure may be at least 10% larger than the width or area of the smaller element. The first and second elements 102 and 104 can accordingly comprise non-deposited elements. Further, directly bonded structures 100, unlike deposited layers, can include a defect region along the bond interface 118 in which nanometer-scale voids (nanovoids) are present. The nanovoids may be formed due to activation of the bonding surfaces 112a and 112b (e.g., exposure to a plasma). As explained above, the bond interface 118 can include concentration of materials from the activation and/or last chemical treatment processes. For example, in embodiments that utilize a nitrogen plasma for activation, a nitrogen peak can be formed at the bond interface 118. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolized (OH-terminated) surface with NH₂ molecules, yielding a nitrogen-terminated surface. In embodiments that utilize an oxygen plasma for activation, an oxygen peak can be formed at the bond interface 118. In some embodiments, the bond interface 118 can comprise silicon oxynitride, silicon oxycarbonitride, or silicon carbonitride. As explained herein, the direct bond can comprise a covalent bond, which is stronger than van Der Waals bonds. The bonding layers 108a and 108b can also comprise polished surfaces that are planarized to a high degree of smoothness.

In various embodiments, the metal-to-metal bonds between the contact pads 106a and 106b can be joined such that copper grains grow into each other across the bond interface 118. In some embodiments, the copper can have grains oriented along the 111 crystal plane for improved copper diffusion across the bond interface 118. The bond interface 118 can extend substantially entirely to at least a portion of the bonded conductive features 106a and 106b, such that there is substantially no gap between the non-conductive bonding layers 108a and 108b at or near the bonded conductive features 106a and 106b. In some embodiments, a barrier layer may be provided under the conductive features 106a and 106b (e.g., which may include copper). In other embodiments, however, there may be no barrier layer under the conductive features 106a and 106b, for example, as described in U.S. Pat. No. 11,195,748, which is incorporated by reference herein in its entirety and for all purposes.

Beneficially, the use of the hybrid bonding techniques described herein can enable extremely fine pitch between adjacent contact pads 106a and 106b, and/or small pad sizes. For example, in various embodiments, the pitch p (i.e., the distance from edge-to-edge or center-to-center, as shown in FIG. 1A) between adjacent conductive features 106a (or 106b) can be in a range of 0.5 microns to 50 microns, in a range of 0.75 microns to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 microns to 30 microns, in a range of 0.25 microns to 5 microns, or in a range of 0.5 microns to 5 microns.

### Example Embodiments of Bonded Structures

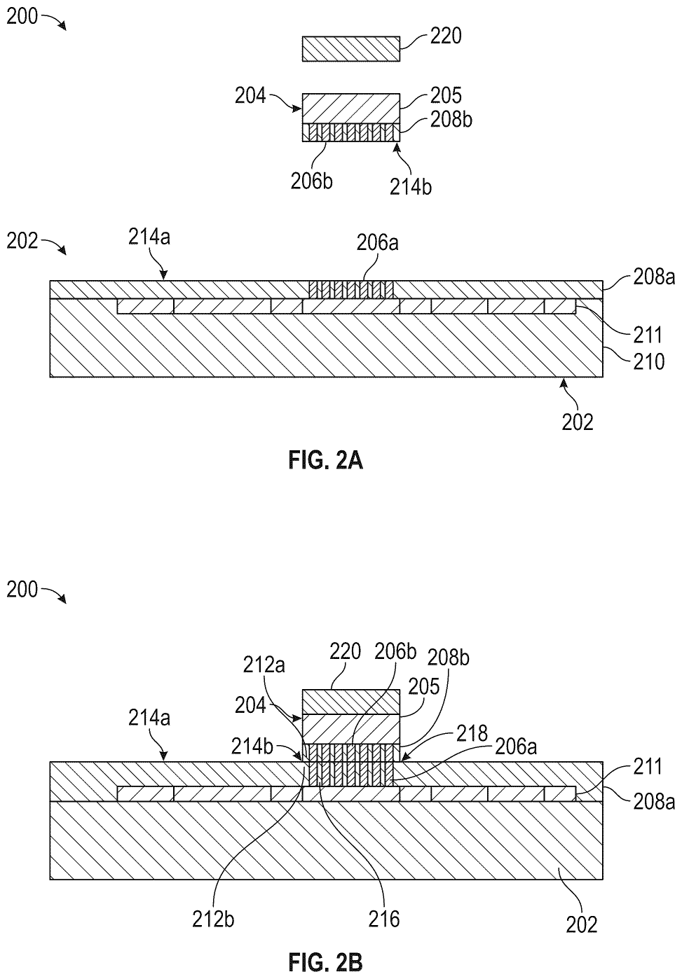

FIG. 2A illustrates a semiconductor element 202 having a bonding layer 208a (e.g., an inorganic dielectric) on a device portion 210 and a security die 204 (which also may be referred to herein as an “security chiplet” and “security chip”) having a second bonding layer 208b prior to bonding. In some embodiments, the first bonding layer 208a can comprise silicon oxide, silicon nitride, silicon oxynitride, silicon oxycarbonitride, or silicon carbonitride. The device portion 210 can comprise a semiconductor material patterned with one or more devices 211 (e.g., one or more active devices, such as transistors, and/or one or more passive devices). Each of the semiconductor element 202 and the security die 204 can have corresponding conductive contact pads 206a, 206b configured to provide an electrical connection to the other element. The contact pads 206a, 206b can comprise discrete conductive pads disposed in a nonconductive field region 208a, 208b (e.g., a nonconductive bonding layer).

The security die 204 (also referred to herein as an encryption chiplet or security chiplet) can comprise a security core 205 comprising silicon and containing encryption and/or decryption logic and memory patterned on a surface of the die. In various embodiments, the memory of the security core 205 can store an encryption key. In some embodiments, the security core 205 can be a chiplet which can also be hardened by software and/or hardware. Further, in some embodiments, the security core 205 can be made very thin and with a reduced footprint so as to beneficially reduce the vertical and horizontal size of the security die 204. For example, the security die 204 comprising the security core 205 can have an area in the range of 50 microns by 50 microns to 150 microns by 150 microns, an area in the range of 75 microns by 75 microns to 125 microns by 125 microns, or an area in the of 90 microns by 90 microns to 110 microns by 110 microns. The security core 205 can be configured to decrypt data to be transferred to the devices 211 disposed in or on the device region 210. The decrypted data or signals can be transferred to the devices 211 by way of the conductive contact features 206a, 206b across the bond interface 218 and traces (not shown) in metallization layers over the semiconductor element 202. The devices 211 can process the decrypted signals or data in any suitable manner. In some embodiments, the processed data or signals can be transferred to the security core 205, which can encrypt the processed signals received from the active circuitry or devices 211. In some embodiments, the security methods provided by the security die 204 can include decryption processing of the data transmitted to the semiconductor element 202 before being processed by the devices 211 (which can comprise patterned processing circuitry and/or active circuitry) of the semiconductor element 202. In some embodiments, the security methods provided by the security die 204 additionally or alternatively includes encryption processing of the data or signals that are transmitted from the semiconductor element 202 to the security die 204 by way of the contact features 206a, 206b.

In various embodiments, the security die 204 can include a protective or an obstructive material 220 to provide an anti-hacking structure against third parties attempting to hack into the security die 204. In some embodiments, the obstructive material 220 can be part of a protective element that is directly bonded (e.g., using dielectric-to dielectric bonding techniques, such as the ZiBond® techniques used by Adeia Corporation of San Jose, Calif.) to a surface (e.g., a back surface) of security die 204 to inhibit external access to the security core 205. The protective element 220 can be directly bonded to a back side of the security die 204. In other embodiments, the obstructive material 220 can be deposited on a one or more surfaces of the security die 204. By including the obstructive material 220 on a chip rather than an entire integrated circuit die 202, processing time and costs may be reduced. The costs of protecting solely the chip 204 can be relatively low. In some embodiments, the obstructive material 220 can be part of a discrete protective element that is directly bonded to the back side of the security die 204. In other embodiments, the obstructive material 220 can alternatively be deposited over the back side of the security die 204 and/or the security core 205.

The obstructive material 220 can include a physically destructive material (e.g., an abrasive and/or hard material) configured to physically damage or destroy tooling that attempts to access the device 211 of the semiconductor element 202, or otherwise prevent physical or mechanical access to the device 211. The obstructive material 220 may have a high shear modulus, a high bulk modulus and may not exhibit plastic deformation. For example, materials with a hardness of at least 80 GPa (for example, as measured on the Vickers scale) can be used for the destructive material. In various embodiments, the destructive material can have a hardness of at least 20 GPa, at least 30 GPa, or at least 50 GPa. For example, the destructive material can have a hardness in a range of 20 GPa to 150 GPa, in a range of 40 GPa to 150 GPa, or in a range of 80 GPa to 150 GPa as measured on the Vickers scale. In another example, the abrasive or destructive material may have a hardness higher than typical materials used in semiconductor chip. For example, hardness of the destructive material may be higher than that of Si, SiO, SiN, SiON, SiCN, etc. In some embodiments, a first hardness of the obstructive material 220 is greater than a second hardness of the semiconductor element 202 or a third hardness of the material at the bonding interface between the semiconductor element 202 and security die 204. An obstructive material comprising an abrasive and/or hard material is described at least in paragraph [0024] as disclosed at least in U.S. Publication 2020/0328162, the entire contents of each of which are incorporated by reference herein in their entirety and for all purposes. Additional examples of protective elements may be found throughout U.S. Publications 2020/0328164, 2020/0371154, and 2020/0328165.

In various embodiments, as explained above, the obstructive material 220 can alternatively or additionally comprise a light-blocking material configured to block light and/or an electromagnetic absorbing or dissipating material to block electromagnetic waves. For example, the obstructive material 220 can be selected to block light at wavelengths in a range of 700 nm to 1 mm, in a range of 750 nm to 2500 nm, or in a range of 800 nm to 2500 nm. The obstructive material 220 can alternatively or additionally be selected or shaped to scatter incident light. The obstructive material 220 can alternatively or additionally be electrically conductive, and may effectively act as electromagnetic shield. The obstructive material 220 can additionally or alternatively absorb the electromagnetic waves. In various embodiments, the obstructive material 220 can be selected to block near infrared (NIR) and focused ion beam (FIB) fault intrusion attempts. In another embodiment, the obstructive material 220 may comprise or may be deposited with one or more layers of optical or infrared filters. The thin film optical filters may act to filter out or modify the optical or IR light irradiated through them in either direction, e.g., light incident upon the circuit to trigger a response or the light emitted from the circuit to detect a response to a hacking technique. An obstructive material comprising light-blocking materials is described at least in paragraphs [0023], [0025], and [0030] as disclosed at least in U.S. Publication 2020/0328162, the entire contents of each of which are incorporated by reference herein in their entirety and for all purposes. Additional examples of protective elements having light-blocking qualities may be found throughout U.S. application Ser. Nos. 17/816,346 and 17/812,675.

FIG. 2B shows a bonded structure 200, according to one embodiment, in which the security die 204 is bonded to the semiconductor element 202, e.g., using a direct hybrid bonding technique. The obstructive material 220 in FIG. 2B can be part of a protective element that is directly bonded to the security die 204. As shown in FIG. 2B, the semiconductor element 202 can have a plurality of contact pads 206a on a front side 214a and the security die 204 can have a plurality of contact pads 206b on a front side 214b, in which the first plurality of contact pads 206a are directly bonded to the second plurality of contact pads 206b. The semiconductor element 202 can be bonded (e.g., directly bonded without an intervening adhesive) to the security die 204 along bonding surfaces 212a and 212b, with the contact pad 206a electrically connected to the contact pad 206b.

In contrast to FIGS. 2A and 2B, FIG. 4 shows an integrated surface die 400 comprising a substrate 404 with devices 402 (e.g., one or more active devices, such as transistors, and/or one or more passive devices) disposed on a surface of the substrate 404 and an encapsulating layer 406 encapsulating the devices 402. The devices 402 can include security processing circuitry for providing encryption and/or decryption for the die 400. As the die 400 does not include a security chiplet, such as security die 204, additional protective features, such as protective element 408, may be provided along the entire length of the die to protect the die. Additionally, security processing circuitry is disposed over a surface of the substrate 404, which takes up valuable horizontal space. Beneficially, the use of the security chip 204 can reduce the footprint as compared to the die 400 of FIG. 4.

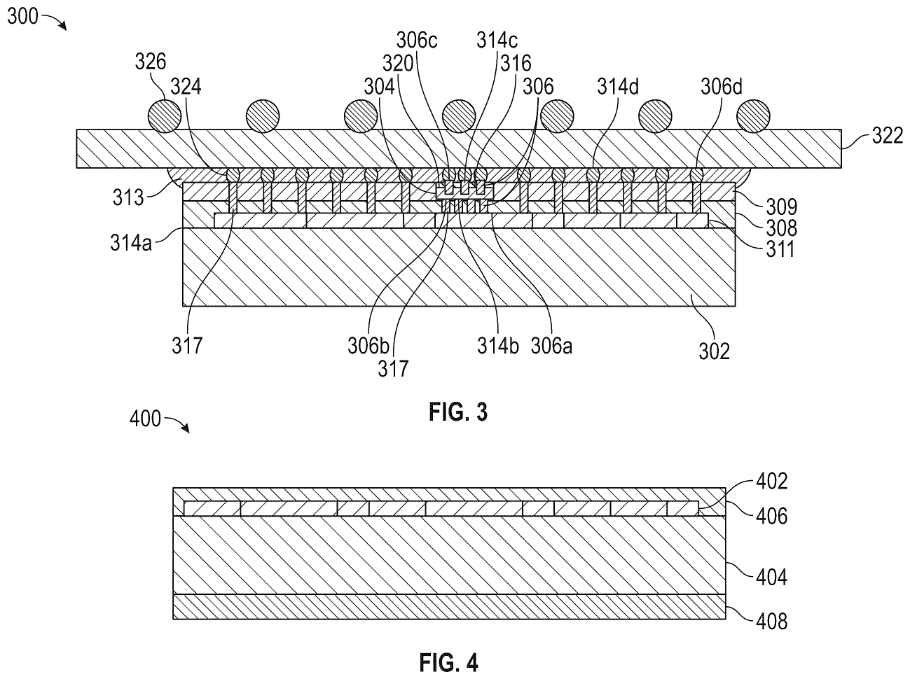

FIG. 3 is generally similar to the embodiment of FIGS. 2A-2B. Unless otherwise noted, the components in FIG. 3 may be the same as or generally similar to like-numbered components of FIGS. 2A-2B. As shown in FIG. 3, the bonded structure 200, including the semiconductor element 302 and security die 304, can be further electrically and mechanically connected to a carrier 322 to form package assembly 300. In some embodiments, the semiconductor element 302 and security die 304 can be connected to the carrier 322 in a flip chip configuration, e.g., by way of a plurality of solder balls 324 or other conductive adhesive. In other embodiments (e.g., embodiments in which the external device comprises another die, interposer, or wafer), the bonded structure 200 of FIG. 2B can be directly bonded to the external device. Each of the first semiconductor element 302, the security die 304, and the carrier 322 can have corresponding conductive contact pads 306 configured to provide an electrical connection to another element. The contact pads 306 can comprise discrete conductive pads disposed in a respective nonconductive field region 308 (e.g., a nonconductive bonding layer). Once connected, an underfill material 313 can be applied around the solder balls 324. The underfill material can comprise an insulating material that isolates the solder balls 324 from one another and connects the carrier 322 to the bonded structure 200.

In this configuration, the semiconductor element 302 can have a plurality of contact pads 306a on a front side 314a and security die 304 can have a first plurality of contact pads 306b on a front side 314b and further include a second plurality of contact pads 306c on a back side 314c. The carrier 322 can include a plurality of contact pads 306d on a front side 314d. The semiconductor element 302 can be bonded (e.g., directly bonded without an intervening adhesive) to the security die 304, with the plurality of contact pads 306a electrically connected to the plurality of contact pads 306b by way of vias 317. The contact pads 306b on the security die 304 can be directly bonded to upper surfaces of the vias 317. The plurality of contact pads 306c at the back of the security die 304 can be electrically connected to the plurality of contact pads 306d on the carrier 322 by the conductive bumps or solder balls 324 In some embodiments, the carrier 322 can further comprise conductive bumps or solder balls 326 to connect the carrier to an external device (such as a system board or other device). In some embodiments, the first semiconductor 302 and the security die 304 can be at least partially encapsulated in an encapsulating material 309, which include an organic dielectric (e.g., a polymer such as a molding compound), or an inorganic dielectric (such as silicon oxide, etc.). As shown vias 317 can extend through the nonconductive field region 308 to connect the devices 311 of the semiconductor element 302 to the pads 306c of the security die 304 (e.g., by way of a direct hybrid bond between a nonconductive region and pads 306c of the security die 304 and the nonconductive field region 308 and vias 317. Further vias 317 can extend from the devices 311 through the nonconductive field region 308 and the encapsulating material 309 to connect the devices 311 to the solder balls 324.

In some embodiments, vias 316 can connect the security chip 304 to the solder balls 324 connected to the carrier 322. As shown, the vias 316 can extend through an obstructive material 320 disposed over and/or around the security chip 304. In some embodiments, a plurality of through substrate vias (TSVs) (not shown) can extend through the security chip 304 to provide electrical communication between the front and backsides of the security chip 304, e.g., to electrically connect the carrier 322 to the devices 311 of the semiconductor element 302. When bonded and/or assembled, the vias 316 can provide additional security measures against debonding and/or hacking due to the inability to access the security die 304 without disrupting the connections (e.g., cutting or severing the vias). In some embodiments, if in the flip chip configuration, the bonded structure 300 can become inoperable when the carrier 322 is disconnected from the vias 316. For example, the carrier 322 can be connected to other devices and/or circuitry, such as the devices 311 and/or the security die, that can monitor a signal to determine if the direct connection has been compromised. If the carrier 322 is removed from the first semiconductor element 302 and security die 304, the removal can trigger a signal along the vias 316 (e.g., detected by a change in impedance, current, voltage, etc.) indicative of the removal. Such removal can disrupt the power supplied to the components of the bonded structure 300, rendering the bonded structure 300 inoperable.

Any portion of any of the steps, processes, structures, and/or devices disclosed or illustrated in one example in this disclosure may be combined or used with (or instead of) any other portion of any of the steps, processes, structures, and/or devices disclosed or illustrated in a different example or flowchart. The examples described herein are not intended to be discrete and separate from each other. Combinations, variations, and some implementations of the disclosed features are within the scope of this disclosure.

While operations may be depicted in the drawings or described in the specification in a particular order, such operations need not be performed in the particular order shown or in sequential order, or that all operations be performed, to achieve desirable results. Other operations that are not depicted or described may be incorporated in the example methods and processes. For example, one or more additional operations may be performed before, after, simultaneously, or between any of the described operations. Additionally, the operations may be rearranged or reordered in some implementations. Also, the separation of various components in the implementations described above should not be understood as requiring such separation in all implementations, and it should be understood that the described components and systems may generally be integrated together in a single product or packaged into multiple products. Additionally, some implementations are within the scope of this disclosure.

Terms of orientation used herein, such as “top,” “bottom,” “proximal,” “distal,” “longitudinal,” “lateral,” and “end,” are used in the context of the illustrated example. However, the present disclosure should not be limited to the illustrated orientation. Indeed, other orientations are possible and are within the scope of this disclosure. Terms relating to circular shapes as used herein, such as diameter or radius, should be understood not to require perfect circular structures, but rather should be applied to any suitable structure with a cross-sectional region that may be measured from side-to-side. Terms relating to shapes generally, such as “circular,” “cylindrical,” “semi-circular,” or “semi-cylindrical” or any related or similar terms, are not required to conform strictly to the mathematical definitions of circles or cylinders or other structures, but may encompass structures that are reasonably close approximations.

Conditional language, such as “may,” “could.” “might.” or “may,” unless specifically stated otherwise, or otherwise understood within the context as used, is generally intended to convey that certain examples include or do not include, certain features, elements, and/or steps. Thus, such conditional language is not generally intended to imply that features, elements, and/or steps are in any way required for one or more examples.

Conjunctive language, such as the phrase “at least one of X, Y, and Z.” unless specifically stated otherwise, is otherwise understood with the context as used in general to convey that an item, term, etc. may be either X, Y, or Z. Thus, such conjunctive language is not generally intended to imply that certain examples require the presence of at least one of X, at least one of Y, and at least one of Z.

The terms “approximately.” “about,” and “substantially” as used herein represent an amount close to the stated amount that still performs a desired function or achieves a desired result. For example, in some examples, as the context may dictate, the terms “approximately,” “about,” and “substantially,” may refer to an amount that is within less than or equal to 10% of the stated amount. The term “generally” as used herein represents a value, amount, or characteristic that predominantly includes or tends toward a particular value, amount, or characteristic. As an example, in certain examples, as the context may dictate, the term “generally parallel” may refer to something that departs from exactly parallel by less than or equal to 20°. All ranges are inclusive of endpoints.

Several illustrative examples of towlines and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures, or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

1. A bonded structure comprising:
a semiconductor element comprising active circuitry; and
a security die electrically connected and directly bonded to a surface of the semiconductor element without an adhesive along a bonding interface, the security die comprising a security core,
wherein the security core contains an encryption logic and a memory, and
wherein the security core is configured to perform at least one of decrypting signals to be transferred to the active circuitry and encrypting signals received from the active circuitry.

2. The bonded structure of claim 1, further comprising vias that electrically connect the security die and the semiconductor element.

3. The bonded structure of claim 1, wherein the semiconductor element and security die are hybrid bonded such that nonconductive regions of the semiconductor element and the security die are directly bonded and conductive regions of the semiconductor element and the security die are directly bonded.

4. The bonded structure of claim 1, further comprising an obstructive material over the security die, the obstructive material configured to inhibit external access to the security core.

5. The bonded structure of claim 4, wherein the obstructive material is part of a protective element, the protective element directly bonded to a surface of the security die.

6. (canceled)

7. (canceled)

8. (canceled)

9. (canceled)

10. (canceled)

11. (canceled)

12. (canceled)

13. (canceled)

14. The bonded structure of claim 1, wherein the semiconductor element comprises a first bonding layer and wherein the security die comprises a second bonding layer directly bonded to the first bonding layer without an adhesive.

15. (canceled)

16. The bonded structure of claim 14, further comprising a first plurality of contact pads in the first bonding layer and a second plurality of contact pads in the second bonding layer, the first plurality of contact pads directly bonded to the second plurality of contact pads.

17. The bonded structure of claim 1, wherein the memory stores an encryption key.

18. A bonded structure comprising:
a semiconductor element comprising active circuitry;
a security die electrically connected and directly bonded to a surface of the semiconductor element without an adhesive along a bonding interface, the security die comprising a security core; and
an obstructive material disposed over a surface of the security die, the obstructive material configured to inhibit external access to the security core.

19. The bonded structure of claim 18, wherein the security core comprises an encryption logic and a memory.

20. The bonded structure of claim 18, wherein the security core is configured to encrypt data to be transferred to the active circuitry and decrypt signals received from the active circuitry.

21. The bonded structure of claim 18, wherein the obstructive material is part of a protective element, the protective element directly bonded to a surface of the security die.

22. The bonded structure of claim 18, further comprising a carrier, the security die mechanically and electrically connected to the carrier.

23. The bonded structure of claim 18, further comprising vias that electrically connect the security die and the semiconductor element.

24. The bonded structure of claim 22, further comprising vias that electrically connect the security die and the carrier.

25. (canceled)

26. (canceled)

27. (canceled)

28. (canceled)

29. (canceled)

30. (canceled)

31. (canceled)

32. (canceled)

33. The bonded structure of claim 18, wherein the semiconductor element comprises a first bonding layer and wherein the security die comprises a second bonding layer directly bonded to the first bonding layer without an adhesive.

34. (canceled)

35. The bonded structure of claim 18, wherein the security die further comprises a through substrate via.

36. A method of forming a bonded structure, the method comprising:
providing a security die with a security core, the security core containing encryption logic and a memory;
directly bonding the security die to a surface of a semiconductor element without an adhesive such that the security die and semiconductor element are electrically connected, the security core configured to perform at least one of decryption of signals to be transferred to the semiconductor element and encryption of signals to be received from the semiconductor element.

37. The method of claim 36, wherein the semiconductor element comprises active circuitry.

38. (canceled)

39. The method of claim 36, further comprising providing an obstructive material over a surface of the security die, the obstructive material configured to prevent external access to the security die.

40. (canceled)
